(19) United States
(12) Patent Application Publication
(10) Pub. No.: US 2010/0039780 A1
(43) Pub. Date: Feb. 18, 2010

(54) Electronic Device for a Vehicle Having a Printed Circuit B

(76) Inventors: Dirk Wendt, Dettingen (DE); Helmut Haeussler, Aichtal (DE); David M. Silva, Nuertigen (DE)

Correspondence Address: K.F. ROSS P.C., 5683 RIVERDALE AVENUE, SUITE 203 BOX 900, BRONX, NY, 10471-0900, US

(21) Appl. No.: 11/989,093

(22) PCT Filed: Apr. 10, 2006
(86) PCT No.: PCT/EP2006/003240

§ 371 Date: Mar. 18, 2009

(30) Foreign Application Priority Data
Jul. 21, 2005 (DE) 10 2005 034 084.9

(51) Int. Cl. H05K 5/00

(52) U.S. Cl. 361/752

(57) ABSTRACT

The invention relates to an electronic device for a vehicle having a printed circuit board (1) with components located thereon for carrying out the function of the electronic device, the printed circuit board (1) being capable of being attached to a vehicle component (8) and having at least one contact face (2) by means of which contact can be made with a printed circuit board (6) of the vehicle component (8), there being provision according to the invention for the contact face (2) of the printed circuit board (1) to be able to be placed in contact directly with a corresponding contact face of the printed circuit board (6) without intermediate connection of contact means.

### TECHNICAL FIELD

The invention is relative to an electronic device for a vehicle with a printed-circuit board in accordance with the features of the introductory part of claim 1.

### PRIOR ART

EP 1,080,513 [U.S. Pat. No. 6,411,259] teaches an antenna amplifier as an electronic device for a vehicle with a printed-circuit board with components on it for functioning of the electronic device.

The printed-circuit board has contact springs on its lower face that make contact in or on a part of the vehicle (here a vehicle window) when the printed-circuit board is set in a holder frame located on the vehicle window. Such a system, also called an ”on-glass system,” has wide use and has proven itself, but also has disadvantages at the same time because the projecting contact springs soldered on the lower face of the printed-circuit board can bend or break off so that no engagement or poor engagement is realized as a result. Furthermore, it is expensive to solder these contact springs on the lower face of the printed-circuit board. In the case of bent or broken-off contact springs, repair of the electronic device is usually too costly to be considered possible.

Instead of contact springs permanently mounted on the lower face of the printed-circuit board the idea has already been considered of using contact springs mounted apart from the part of the vehicle as well as from the printed-circuit board. Such contact springs with a lamellar form or so-called contact pads consisting of an electrically conductive and elastically deformable plastic are already known.

However, all these measures have the disadvantage that additional means is provided for engagement a contact of the printed-circuit board with a corresponding contact of the part of the vehicle.

### OBJECT OF THE INVENTION

The object of the invention is therefore to make an electronic device for a vehicle with a printed-circuit board that can still engage a conductor of the part of the vehicle but avoids the above-described disadvantages.

This object is attained by the features of claim 1.

According to the invention the electronic device for a vehicle with a printed-circuit board is designed in such a manner that the contact of the printed-circuit board directly contact the corresponding contact of the conductor without the interposition of an intermediate contact. As a result, intermediate contacts of whatever type can be eliminated in the electrical engagement of the contact of the printed-circuit board with a corresponding contact of the conductor on the part of the vehicle. In addition to the reduction of the component expense there is increased safety of the contacting since only two contacts, namely that of the printed surface board and that of the conductor, still have to engage one the contact of the printed-circuit board with the intermediate contact and on the other hand the intermediate contact with a contact of the conductors) having to engage each other. Moreover, assembly expense is reduced in an advantageous manner so that handling of previously provided intermediate contacts is eliminated.

In a further development of the invention the printed-circuit board (with or without a housing or protective covering, e.g. in the form of an extrusion coat) can be set in a holder and the holder fastened on top of or on the part of the vehicle. In addition to the possibility of fastening the electronic device and/or the printed-circuit board directly on top of or on the part of the vehicle (e.g. by an adhesive), there is the advantage here that in case of a defect the printed-circuit board of the electronic device, which can also be designed to be modular with several printed-circuit boards, can be replaced. Such a replacement procedure is especially simple since the printed-circuit board only has to be taken out of the holder and replaced, after which the new printed-circuit board is then set into the holder and engagement with the conductor of the part of the vehicle takes place simultaneously with the installation. Expensive removal and replacement of previously provided intermediate contacts is eliminated here. The holder itself can be separate part from the part of the vehicle and can be produced, e.g. in a plastic injection-molding process and secured to the part of the vehicle by an adhesive. It is alternatively conceivable that the part of the vehicle itself is designed in such a manner that it forms the holder for the printed-circuit board of the electronic device.

In a further development of the invention the conductor is designed as a flat conductor on or in the part of the vehicle. This has the advantage that the conductor is available already with the manufacture of the part of the vehicle or subsequently in an especially space-saving manner and the direct engagement with the contact of the printed-circuit board is readily possible on account of the flexibility of the flat conductor, in particular as regards its deformability. While it is conceivable on the one hand that the flat conductor is provided in or on the part of the vehicle and comprises a contact, e.g. in its end area, it can be possible in a further embodiment of the invention that the conductor, in particular a flat conductor, is mounted on a support, in particular a support foil or a rigid support, which support is mounted for its part on or in the part of the vehicle. Thus, the conductor, in particular a complex conductor with optionally several conductive parts, can be mounted on a support foil or a rigid support, which support is then mounted on the part during the manufacture of the part of the vehicle or subsequently. It is understood here that the holder as well as the part of the vehicle consist (completely or in the areas in which the holder is located) of an electrically non-conductive and therefore dielectric material. This material can be transparent (vehicle window) or can consist of a non-transparent material (e.g. vehicle roof, tailgate, bumper or other part of the vehicle).

On the whole, the design of the conductor as a flat conductor and its arrangement on a support offers the advantage of great freedom of design as well as a flat construction that is especially space-saving.

A further development of the invention provides that the conductor is mounted on a support, especially a support foil or a rigid support that itself is provided inside the holder of the printed-circuit board on the part of the vehicle. Thus, there are two possibilities available for mounting the conductor: Namely, as a conductor in or on the part of the vehicle with or without a support and also mounting of the conductor, again with or without a support, on the printed-circuit board of the electronic device. These two possibilities are particularly to be considered if the conductor is to fulfill functions for which a rather large or rather small surface area is required. If, e.g. the conductor serves as an antenna structure with which high-frequency signals are received in the vehicle or are emitted from it, a rather large surface area of the conductor is required that preferably extends in or on the part of the vehicle (here the vehicle window, the trunk lid or the like). On the other hand, if it is sufficient that the high-frequency signals to be sent or received do not require a large surface area (e.g. signal transmission inside the interior of the vehicle when the electronic device is also provided there), the conductor can then also be provided with or without a support only in the area of the printed-circuit board or its holder. The above also applies to the type of high-frequency signals, in particular their frequency. Even if the high-frequency signals are to be emitted outside of the vehicle or are to be received outside of the vehicle, it can be possible as a function of the frequency of these signals that the conductor (=antenna structure) extend only in on the surface of the printed-circuit board of the electronic device.

A special embodiment of the invention provides that the conductor is integrated into the holder for the printed-circuit board. This means that when the holder for the printed-circuit board is manufactured, the conductors are already integrated in it, which is possible for example with a plastic injection-molding process. This separately manufactured support with the integral conductors is provided on the part of the vehicle, the printed-circuit board is installed and makes direct contact with the conductors provided there. It is alternatively conceivable that the support is manufactured at the same time as the part of the vehicle and is provided with the conductor. In this case a part of the vehicle with integrated holder for receiving the printed-circuit board of the electronic device is available in which the conductor is integrated especially flatly in the part of the vehicle or in particular on the support (optionally also flat).

A further development of the invention provides means for pressing the contact of the conductor against the contact of the printed-circuit board. This ensures that the necessary contact forces are provided and that electrical contact safety is ensured. Moreover, the pressing means ensures compensation of tolerances as well as compensation of play that can occur as temperature fluctuates. Moreover, they are advantageous in order to compensate for vibrations that occur during operation of the vehicle. Moreover, they make possible a detachable connection of the contacts engaging each other, which is necessary for replacement of the printed-circuit board of the electronic device.

In a special embodiment of the invention the pressing means is designed as a spring leg and in particular a component of the holder for the printed-circuit board. The design as a spring leg is advantageous because it can be arcuate and thus generates the necessary, somewhat spread out pressure. Moreover, this design has an especially simple construction and can be readily provided with the manufacture of the holder. However, even other construction designs and arrangements of the means generating the pressure force are conceivable.

Thus, e.g. all types of elastically deformable “pressure pads” are also possible here as well as conductive, non-conductive metallic and other springs of all types. However, the invention has the advantage that these extra parts can be dispensed with a since the spring means are formed directly on the holder frame and require no further expense.

### BRIEF DESCRIPTION OF THE DRAWINGS

Different nonlimiting embodiments of the invention are described in the following and shown with reference to the figures.

Therein:

FIG. 1 shows a conductor mounted on a support foil,

FIG. 2 shows a conductor mounted in the part of the vehicle,

FIG. 3 shows a conductor mounted inside a holder of the printed-circuit board,

FIG. 4 shows the conductor mounted directly on the holder 3.

### WAYS OF CARRYING OUT THE INVENTION

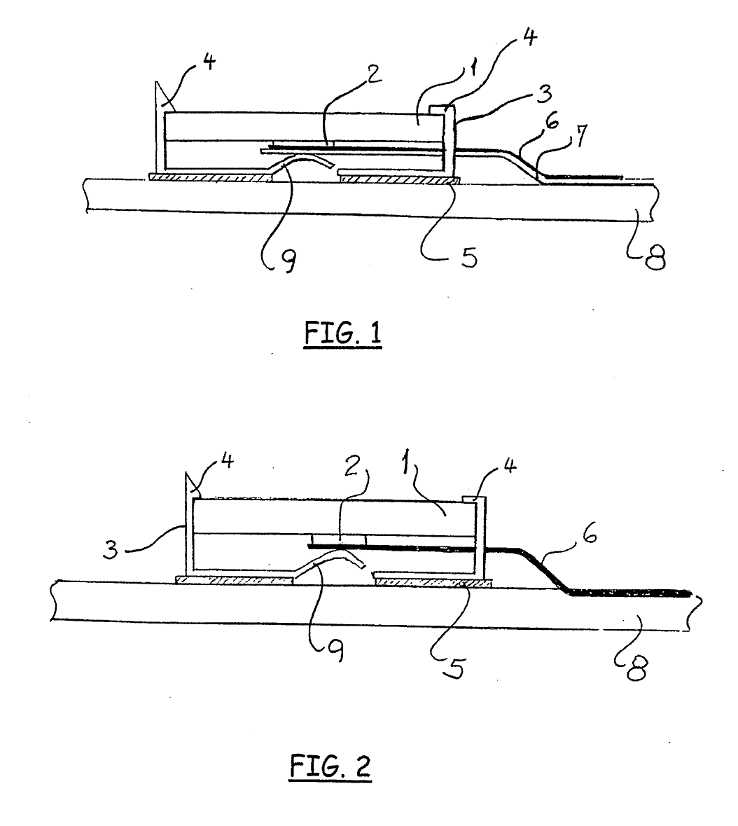

FIG. 1 shows, in as far as details are shown, a printed-circuit board 1 of an electronic device, in particular of an antenna amplifier of a vehicle. Electrical and electronic components are provided on the printed-circuit board 1 for carrying out the function of the electronic device and have been omitted here for clarity of view. The printed-circuit board 1 comprises at least one contact 2 on its lower face and as a rule several contacts. In this embodiment the printed-circuit board 1 is fitted in a the holder 3 shaped to latch with the printed-circuit board 1 and having latch formations 4 to this end. The holder 3 is secured by an adhesive layer 5; however, other detachable or non-detachable fasteners are conceivable.

Contacts 6, e.g. flat conductors, that are provided in an appropriate number for the contacts 2 of the printed-circuit board 1 are mounted on a support designed here as support foil 7. This support foil 7 with conductors 6 provided on it is mounted here on a part of the vehicle but can also be inside the part of the vehicle and can have an end extending out of the vehicle part 8 to the contact 2 and even beyond it. That is, the conductive trace can go further on the other side of the holder 3 (e.g. a holder frame) or it can extend into the holder frame from both sides. After the holder 3 has been fastened onto the vehicle part 8 by the adhesive layer 5, the printed-circuit board 1 can be set into the holder 3, to which end the edge (or another area, e.g. a middle area) of the conductors 6 makes contact with the respective contacts 2. In this instance the holder 3 with the installed printed-circuit board 1 is designed in such a manner that the contact 2 direct engages the respective conductor 6 without further intermediate contacts having to be interposed or other means generating pressure force. However, in the embodiment according to FIG. 1 additional means generating pressure force is provided that is designed as spring leg 9 that is part of the holder 3. This spring leg 9, of which there is one for each of the contacts 2, presses the conductor 6 against the contact 2 in a continuous but detachable manner and without the interposition of other intermediate contacts.

FIG. 2 shows that the conductors 6 are provided on or in the vehicle part 8 without the support foil 7. Otherwise this is the same as in FIG. 1 regarding the assembly of the printed-circuit board 1 and the engagement of its contact 2 with the conductor 6.

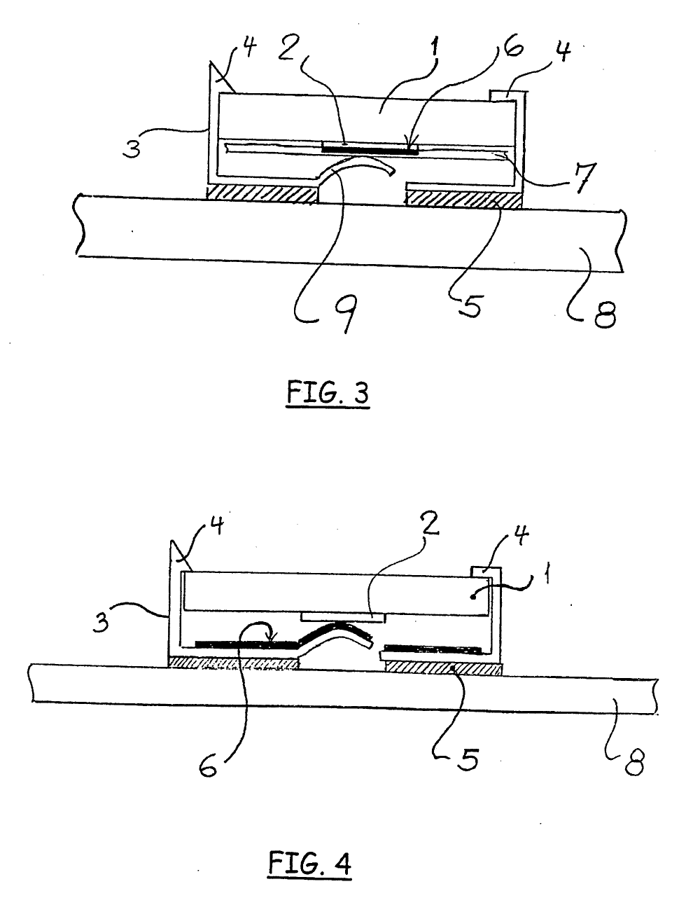

FIG. 3 shows an alternative design in which the conductor 6 is provided on a support, in particular a support foil 7 or a rigid support (even a printed-circuit board) and the support foil 7 is provided inside the holder 3. Whereas FIGS. 1 and 2 show that the conductors 6 extend over a nonconductive the vehicle part 8 material, which part of the vehicle is in particular flat, the conductors 6 in the embodiment according to FIG. 3 extend only inside the holder 3. Such extension of the conductors 6, that function as antenna structures, can be sufficient depending on the wave length of the high-frequency signals received or emitted via the conductors 6 or depending on the frequencies used. Here too the contacts of the conductors 6 are again pressed on the respective contacts 2 of the printed-circuit board 1, in particular with or without a spring 9.

FIG. 4 shows that the conductor 6 is mounted directly on the holder 3. Corresponding possibilities for the metallic coating of plastic parts are sufficiently known (MID, galvanic processes, etc.). The conductor 6 is on a face of the holder 3 turned toward the printed-circuit board 1 but can also be applied as an alternative or also on the lower face of the holder 3 (that is, toward the vehicle part 8).

The embodiments according to FIGS. 1 to 4 show that the holder 3 is separate from the vehicle part 8. However, it is also conceivable here that the holder 3 and the vehicle part 8 are unitary with each other. It is likewise conceivable to allow the conductors 6 to extend not only inside the vehicle part 8 or to arrange them inside the holder 3 but to also form the unitarily inside the holder 3. In the embodiment according to FIG. 3 the fixing of support foil 7 (or alternatively of a rigid support) can take place by spring legs 9 or other locking or pressure means. Likewise, the vehicle part 8 does not have to be built to be planar but can have any two- or three-dimensional shape.

Note also in conclusion that is also conceivable as an alternative to the embodiments according to FIGS. 1 to 3, in which the printed-circuit board 1 is set into the holder 3, that there are other possibilities for fixing the printed-circuit board 1 on the vehicle part 8. Thus the printed-circuit board 1 can be fastened to the part of the vehicle at points or flatly, e.g. by screws, clips, other latch formations, caulking, adhesion or the like. Care should be taken in all these constructive possibilities that along with the fixing of the printed-circuit board on the vehicle part 8 the contact 2 (or the several contacts) of the printed-circuit board 1 are provided in the proper position relative to the regions 6, that is, its contacts, in order that direct engagement of the contacts with each other can take place without the interposition of other intermediate contacts.

### LIST OF REFERENCE NUMERALS

1. Printed-circuit board
2. Contact
3. Holder
4. Latch formations
5. Adhesive layer
6. Conductors
7. Support foil
8. Part of the vehicle
9. Spring leg

1. An electronic device for a vehicle with a printed-circuit board with components located on it for carrying out the function of the electronic device, the printed-circuit board being fastened to a part of the vehicle and comprising at least one contact with which one conductor of the part of the vehicle can be contacted wherein the contact of the printed-circuit board can be brought into direct contact with a corresponding contact of the conductor without the interposition of an intermediate contact.

2. The electronic device according to claim 1 that wherein the printed-circuit board is fitted in a holder and the holder is fastened on top of or on a part of the vehicle.

3. The electronic device according to claim 1 that wherein the conductor is designed as a flat conductor provided on or in the part of the vehicle.

4. The electronic device according to claim 3 that wherein the conductor is provided on a support foil or a rigid support itself provided on or in the part of the vehicle.

5. The electronic device according to claim 1 wherein the conductor is provided on a support, especially a flat foil or a rigid support provided for its part inside the holder.

6. The electronic device according to claim 1 wherein means is provided for pressing the contact of the conductor against the contact of the printed-circuit board.

7. The electronic device according to claim 6 wherein the pressing means is designed as a spring leg.

8. The electronic device according to claim 7 that wherein the spring leg is a component of the holder.

9. The electronic device according to claim 1 wherein the printed-circuit board can be latched on the holder and that the contact of the printed-circuit board can be engaged directly with the corresponding contact of the conductor simultaneously with the insertion of the printed-circuit board into the holder.

10. The electronic device according to claim 1 wherein the conductor is integrated in the holder or that the conductor is provided directly on the holder.
